(19) United States
(12) Patent Application Publication
(10) Pub. No.: US 2016/0233956 A1
(43) Pub. Date: Aug. 11, 2016

(54) OPTICAL FIBER LINK MONITORING APPARATUS AND METHOD CAPABLE OF TRACE-BASED AUTOMATIC GAIN CONTROL

(71) Applicant: ELECTRONICS AND TELECOMMUNICATIONS RESEARCH INSTITUTE, Daejeon (KR)

(72) Inventors: Hun Sik KANG, Daejeon-si (KR); Jong Hyun LEE, Daejeon-si (KR); Jyung Chan LEE, Daejeon-si (KR); Seung Il MYONG, Daejeon-si (KR)

(21) Appl. No.: 15/015,628

(22) Filed: Feb. 4, 2016

(30) Foreign Application Priority Data
Feb. 5, 2015 (KR) 10-2015-0018180

(51) Int. Cl. H04B 10/079; H03G 3/30

(52) U.S. Cl. CPC H04B 10/07955; H03G 3/3084

(57) ABSTRACT

An optical fiber link monitoring apparatus for detecting a failure in an optical fiber link by analyzing a trace of a received signal that has been transmitted to and reflected from said optical fiber link. The optical fiber link monitoring apparatus includes a variable gain amplifier (VGA), an analog/digital converter (ADC), and a controller. The VGA amplifies a gain of the received signal, for which the ADC converts the gain-amplified signal into a digital signal. The controller then analyzes a digital signal trace and adjusts the gain of the VGA according to the analysis result.

### CROSS-REFERENCE TO RELATED APPLICATION(S)

This application claims priority from Korean Patent Application No. 10-2015-0018180, filed on Feb. 5, 2015, in the Korean Intellectual Property Office, the disclosure of which is incorporated herein by reference in its entirety.

### BACKGROUND

1. Field

The following description relates to an optical fiber link monitoring apparatus, and particularly, to an optical fiber link monitoring apparatus using an optical time-domain reflectometer (OTDR) technology.

2. Description of Related Art

An optical time-domain reflectometer (OTDR) is an instrument that can detect flaws, such as damages sustained, in optical communication networks, and is generally used to locate such flaws in an optical fiber link. The OTDR detects or locates flaws in an optical network by sending out a probe signal to an optical fiber link for monitoring and then analyzing the reflection of said signal. Mainly there are two types of reflections that can occur in optical fibers. The first type of reflection occurs due to Rayleigh backscattering, whereby parts of the scattered light is reflected. The second type of reflection is Fresnel reflection, which occurs at the interface of two materials of the optical fiber that have different refractive indices. The amount of reflection due to Rayleigh backscattering increases with the intensity of incident light, while the amount of Fresnel reflection increases proportionally to the difference between two refractive indices.

FIG. 1 is a diagram illustrating a basic principle of operation of an OTDR. The OTDR emits a probe signal to an optical fiber link in order to inspect the physical condition of an optical fiber link for any flaws, such as breakage, losses, or any bent portions. Said probe signal is a single pulse or an encoded code that is emitted through a laser. After probe signal emission, the OTDR then analyses the signal that has been reflected back from the opposite side. As shown in FIG. 1, if a splicing point between optical fibers or an optical connector exists in the middle of the optical fiber link, Fresnel reflection occurs between the two optical fibers due to differing refractive indices of said optical fibers, and hence a reflected signal returns to the OTDR. In addition, while the probe signal is traveling through the optical fibers, some signals undergo Rayleigh backscattering, to which such signals are continuously reflected back to the OTDR. Rayleigh backscattering is proportional to the amplitude of the probe signal, which is why as the amplitude of probe signal decreases exponentially in proportion to losses in optical fibers, the fiber losses can be detected through Rayleigh backscattering. The OTDR measured duration varies with the length of the optical fiber link, where said duration is calculated by measuring the time it takes for the probe signal to make a round-trip journey; this measured duration is compared to a track record of reflected signals (also known as OTDR traces) so that the OTDR can detect the state of the optical fiber link.

Meanwhile, to obtain an accurately measured OTDR trace, it is important to increase the signal-to-noise ratio (SNR) of the probe signal. To this end, the amplitude of the signal sent to an analog/digital converter (ADC) in a reception path should be high enough to increase the SNR of the ADC. To do so, an automatic gain controller that can adjust a gain of a variable gain amplifier (VGA) to a level suitable of an ADC input range is required.

In data communications, the automatic gain controller calculates an average voltage of an input signal (i.e., a square root of an average power of the input signal), obtains a ratio of a target voltage to the average voltage, and sets a needed gain in the VGA. The automatic gain controller obtains an average power of the input signal during a specific observing window. At this time, the obtained average power value is not quite different from the other intervals of said signal. That is, because a peak-to-average ratio (PAR) is not high and hardly changes during intervals of the signal, the loss of SNR of the ADC is insignificant even if the target voltage of an input signal to the ADC were to be set in consideration of PAR.

However, in the case of an OTDR, the amplitude of reflected signal changes with the state of an optical fiber to be measured, and hence the average value of a specific observation window is significantly different from an average value of the other intervals. FIG. 2 is a graph showing such a difference. As shown in FIG. 2, if the amplitude of a signal is adjusted according to an average power, even when the signal's PAR is high, then an adjusted signal may become too small or too large compared with the ADC's input range, and hence an SNR of the ADC may deteriorate. Thus, in the case of automatic gain control based on an average power, a dynamic range of the ADC cannot be fully utilized due to a varying PAR of a signal, resulting in a deterioration of an SNR of an OTDR trace signal, and in turn failure of accurate analysis of the state of the optical fiber link.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided an optical fiber link monitoring apparatus for detecting a failure in an optical fiber link by analyzing a trace of a received signal which has been transmitted to and reflected from the optical fiber link, the optical fiber link monitoring apparatus including: a variable gain amplifier (VGA), an analog/digital converter (ADC), and a controller. The VGA may amplify a gain of the received signal. The ADC may convert a gain-amplified signal into a digital signal. The controller may analyze a digital signal trace and control a gain of the VGA according to the analysis result.

The controller may include a peak finder configured to search for a peak in the digital signal trace and a gain adjuster configured to adjust the gain of the VGA according to the found peak.

The peak finder may include a peak candidate identifier and a peak selector. The peak candidate identifier may determine a peak candidate based on a current input sample value input from the ADC, a previous input sample value delayed by an increment of one sample and another previous input sample value delayed by increments of two samples, wherein when the one-sample-delayed input sample value is the greatest, the peak candidate identifier determines the one-sample-delayed input sample value as a peak candidate. The peak selector may select a peak from peak candidates.

The gain adjuster may calculate a gain error based on a ratio of a target value to a peak of the trace, calculate a gain control value by reflecting the gain error to a current gain value, and adjust the gain of the VGA using the gain control value.

The gain adjuster may search for a gain control value that corresponds to a target value and the peak of the trace from a lookup table, and adjust the gain of the VGA using the found gain control value.

In response to occurrence of an overflow in which the amplitude of an input signal exceeds an input range of the ADC, the gain adjuster may reduce the gain control value.

The controller may further include an automatic gain controller. The automatic gain controller may control transmission of a probe pulse for automatic gain control (AGC) and controls operations of the peak finder and the gain adjuster after a designated period of time since the transmission of the probe signal.

In another general aspect, there is provided an automatic gain control (AGC) method applied to an optical fiber link monitoring apparatus, the trace-based AGC method including: analyzing a digital signal trace; and adjusting a gain of the VGA according to the analysis result.

The analysis of the digital signal trace may include searching for a peak in the digital signal trace, and the adjusting of the gain may include adjusting the gain of the VGA according to the found peak.

The search of the peak may include: determining a peak candidate based on a current input sample value input from the ADC, a previous input sample value delayed by an increment of one sample and another previous input sample value delayed by increments of two samples, wherein when the one-sample-delayed input sample value is the greatest, the one-sample-delayed input sample value is determined as a peak candidate; and selecting a peak from peak candidates.

The adjusting of the gain may include: calculating a gain error based on a ratio of a target value to a peak in the trace; calculating a gain control value by reflecting the gain error to a current gain value; and adjusting the gain of the VGA using the gain control value.

The adjusting of the gain may include, in response to occurrence of an overflow in which the amplitude of an input signal exceeds an input range of the ADC, reducing the gain control value.

Other features and aspects will be apparent from the following detailed description, the drawings, and the claims.

### BRIEF DESCRIPTION OF THE DRAWINGS

FIG. 1 is a diagram illustrating a basic principle of operation of an OTDR.

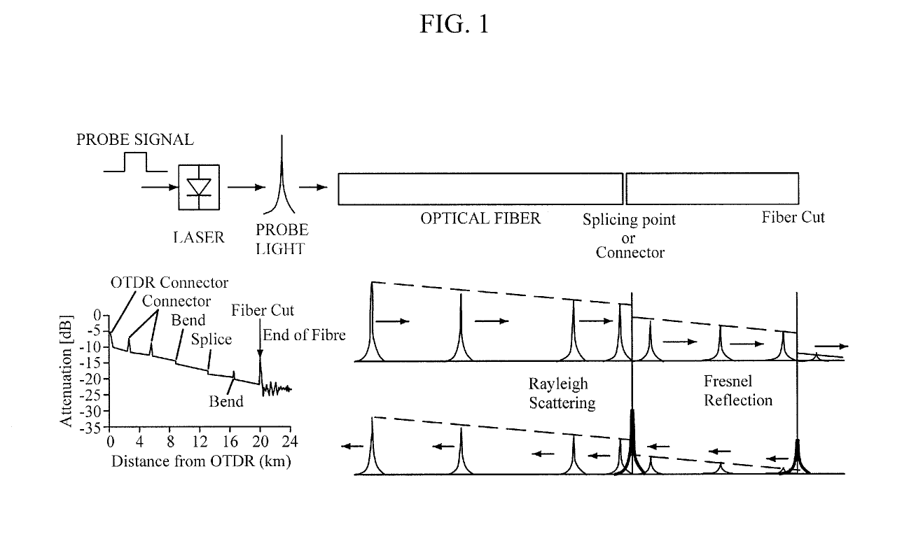

FIG. 2 is a graph illustrating variances of peak-to-average ratios (PARs) depending on changes in the amplitude of a reflected signal.

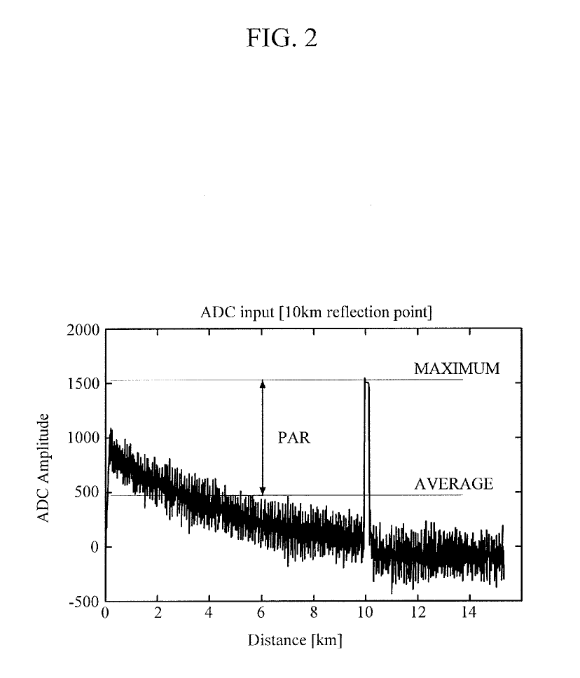

FIG. 3 is a block diagram illustrating an optical fiber link monitoring apparatus according to an exemplary embodiment.

FIG. 4 is a block diagram illustrating a configuration of a peak finder according to an exemplary embodiment.

FIG. 5 is a graph illustrating signals of FIG. 4.

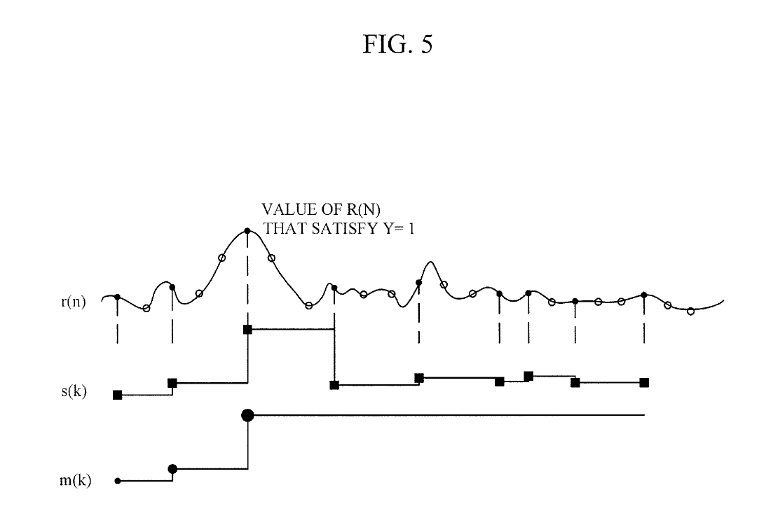

FIG. 6 is a block diagram illustrating a gain error calculator according to an exemplary embodiment.

FIG. 7 is a diagram illustrating a process carried out by an automatic gain controller according to an exemplary embodiment.

FIG. 8 is a diagram illustrating different stages undergone by the automatic gain controller.

FIG. 9 is a flowchart illustrating a trace-based automatic gain control method according to an exemplary embodiment.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

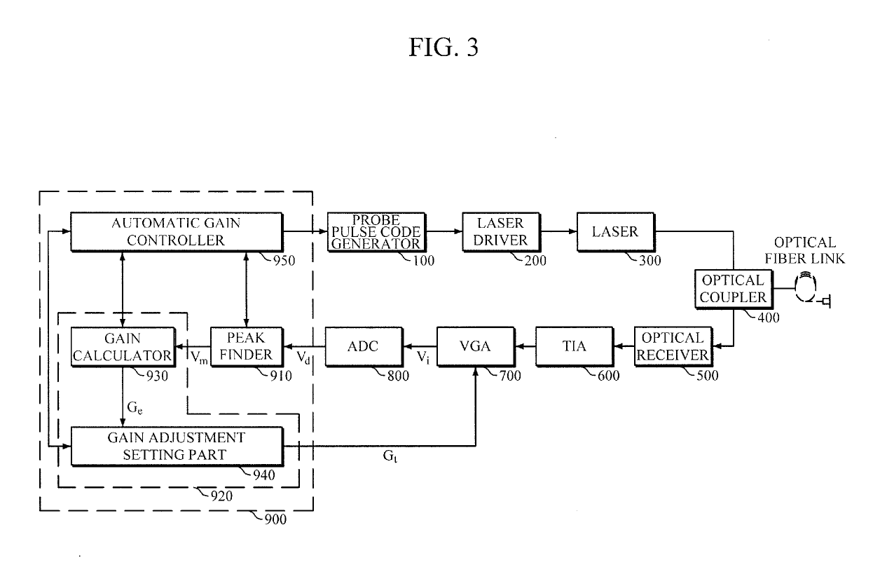

FIG. 3 is a block diagram illustrating an optical fiber link monitoring apparatus according to an exemplary embodiment. The optical fiber link monitoring apparatus transmits a monitoring signal to an optical fiber link and detects a failure in the optical fiber link through a signal reflected back from the optical fiber link. To this end, the optical fiber link monitoring apparatus may include a probe pulse code generator 100, a laser driver 200, a laser 300, an optical coupler 400, an optical receiver 500, a transimpedance amplifier (TIA) 600, a variable-gain amplifier (VGA) 700, an analog/digital converter (ADC) 800, and a controller 900. The probe pulse code generator 100, the laser driver 200, and the laser 300 are used to transmit a monitoring signal, and the configurations thereof are well known. A probe pulse, created by a probe pulse code generator 100, is generated by the laser driver 200 and the laser 300 so that an optical signal is created. The optical signal is transmitted to the optical fiber link through the optical coupler 400; once the optical signal reaches the optical fiber link, a reflection signal is created, to which the reflected signal travels back from the optical fiber link via the optical coupler 400 and is received by the optical receiver 500.

Configurations of the optical receiver 500, the TIA 600, the VGA 700 and the ADC 800, which are used to receive and process the signal reflected from the optical fiber link, are well known. The optical receiver 500 converts a received optical signal into an electrical current signal, and the TIA 600 converts the electric current signal into a voltage signal. The VGA 700 amplifies the gain of a signal output from the TIA 600 to a level that is optimal to an input signal range of the ADC 800, and thereby a signal-to-noise ratio (SNR) of a received signal is increased. The ADC 800 converts an analog signal Vᵢ into a digital signal V_{d} and transmits the digital signal V_{d} to the controller 900.

The controller 900 may be a digital signal processor (DSP), and may analyze a state of the optical fiber link based on a digital signal input from the ADC 800. Further, the controller 900 may analyze a digital signal trace and adjust a gain of the VGA 700 according to the analysis result. In one aspect, the controller 900 includes a peak finder 910 and a gain adjuster 920. The peak finder 910 searches for a maximum value, i.e., peak Vₘ, in the digital signal trace. Then, the gain adjuster 920 adjusts the gain of the VGA 700 according to the peak that is found. As such, if the gain is adjusted according to the peak found in the trace, a dynamic range of the ADC 800 can be fully utilized regardless of a varying peak-to-average ratio (PAR).

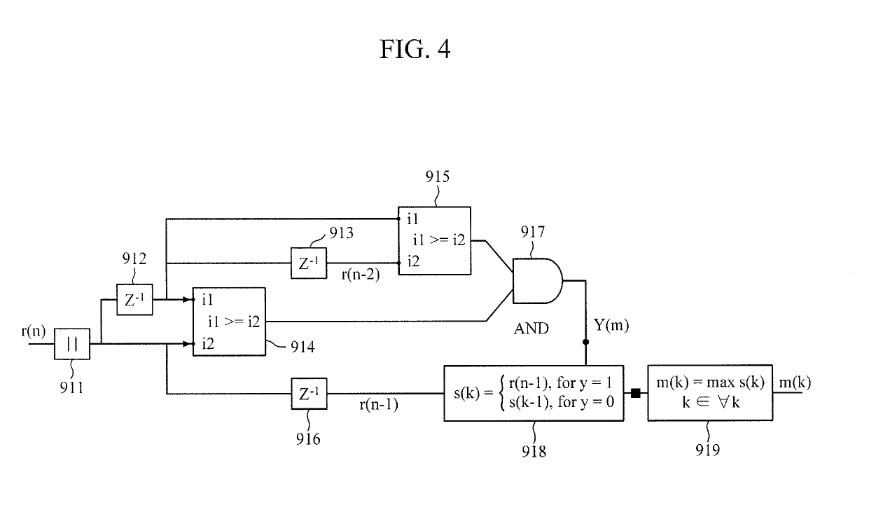

FIG. 4 illustrates a configuration of the peak finder 910. Procedures undertaken by the peak finder 910 for finding a peak in a trace will be described with reference to FIG. 4. An absolute value 911 of an input signal r(n) is obtained, for which a negative value of the input signal is changed into a positive value. Then, the input sample value r(n) is delayed by an increment of one sample (as depicted in 912), and a first comparator 914 compares r(n), a current input sample value, with r(n−1), a previous input sample value. If r(n−1) is greater than r(n), the first comparator 914 outputs “1”; otherwise, “0” is output. A second comparator 915 compares r(n−1) with r(n−2), r(n−2) being a sample value that has been delayed by an increment of one sample more than r(n−1). The second comparator 915 outputs “1” if r(n−1) is greater than r(n−2). That a value of one point is the maximum value means the value of said point is greater than values the previous and later points in the immediate vicinity of said point. Thus, if outputs from the first comparator 914 and the second comparator 915 are “1” and a result Y(m) of an AND operation (as depicted by 917) on the outputs from both the first and second comparators 914 and 915 is “1,” then it can be surmised that the point of r(n−1) is the peak.

If Y(m) is “1” with respect to r(n−1) which is delayed by an increment of one sample depicted as Z⁻¹ in 916, a peak candidate identifier 918 determines that the point of r(n−1) is a peak candidate. The peak candidate identifier 918 may determine multiple points along r(n−1) as peak candidates if the results Y(m) are “1” with respect to r(n−1). This may be represented by Equation 1 as below.

$$s ( k ) = \{ \begin{matrix}r ( n - 1 ) , for y = 1 \\ s ( k - 1 ) , for y = 0\end{matrix} \qquad ( 1 )$$

An output s(k) of the peak candidate identifier 918 is shown in FIG. 4. A peak selector 919 searches for a peak from among peak candidate values. m(k), i.e., the peak found by the peak selector 919 from among the peak candidates s(k), may be represented by Equation 2 as below.

$$m ( k ) = {max}_{k ∈ ∀ k} s ( k ) \qquad ( 2 )$$

In one aspect, the gain adjuster 920 calculates a gain error from a ratio of a target value to a peak in the trace, calculates a gain control value by applying the gain error to a current gain value, and adjusts a gain of the VGA 700 using the gain control value. As shown in FIG. 3, the gain adjuster 920 may include a gain calculator 930 and a gain adjustment setting part 940. The gain calculator 930 receives Vₘ, i.e., a peak value found by the peak finder 910, and calculates a difference between the peak value Vₘ and a target value Vₜ, which is a value designated for fully utilizing the dynamic range of the ADC 800.

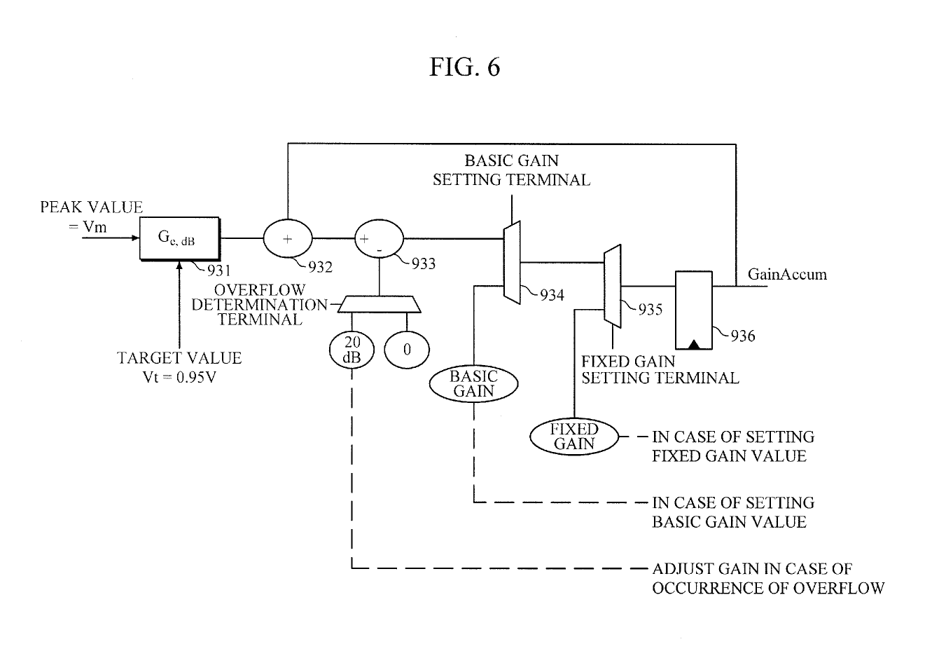

FIG. 6 illustrates a configuration of the gain calculator. A gain error calculator 931 computes a gain value to be adjusted relative to a ratio of the target value Vₜ to the peak value Vₘ. Said gain value may be obtained by Equation 3 as below.

$${G}_{e , dB} = 20 \times {log}_{10} ( \frac{{V}_{t}}{{V}_{m}} ) \qquad ( 3 )$$

The gain control value is used for obtaining a target value Vₜ while a gain value is one set in the VGA 700, and it is between these values, Vₜ and the gain value, that their difference is calculated. Said difference, which is the gain control value, is one which may be added to the current gain value so as to obtain the value of a gain that allows an ADC input to reach the target value Vₜ. A gain adder 932 adds the gain error and the current gain. If an overflow in which the amplitude of the input signal Vᵢ exceeds an input range of the ADC 800 occurs due to the added gain value, a gain attenuator 933 drastically reduces the gain. The ADC 800 may detect the overflow and send a report to the controller 900, or the controller 900, itself, may detect the overflow. When an overflow occurs, a gain is reduced by a designated level, which is 20 dB in FIG. 6. A certain overflow threshold may be set by an overflow setting terminal, for which if a gain has an overflow that is beyond the threshold, the gain attenuator 933 deduces 20 dB from the added gain value resulting from the gain adder 932. A final gain control value “GainAccum” is stored in a gain storage part 936. The gain storage part 936 may be a first-in-first-out (FIFO) buffer. The gain adjustment setting part 940 adjusts a gain using the gain control value stored in the gain storage part 936 and according to properties of a gain control terminal of the VGA 700.

Furthermore, the gain calculator 930 may further include a basic gain setter 934 and a fixed gain setter 935. The basic gain setter 934 is a MUX allows for the selection and output of a basic gain set that has been set as a default, while the fixed gain setter 935 is a MUX that allows for the selection and output of a fixed gain that has been newly set by an external controller. Either one of the basic gain setter 934 or the fixed gain setter 935 may be omitted.

The gain calculator 930 may create a lookup table LUT using gain errors calculated by the gain error calculator 931. A gain error value that corresponds to each peak value is recorded in the lookup table. In one exemplary embodiment, the gain calculator 930 primarily searches for a gain error value that corresponds to a peak from the lookup table, and if the gain error value is present, the gain calculator 930 may use the found gain error value in calculating the gain control value. Otherwise, the gain calculator 930 may use the gain error value obtained from the gain error calculator 931 in calculating the gain control value. In another exemplary embodiment, the gain calculator 930 may have a lookup table search function, rather than having the gain error calculator 931. The lookup table may be created in advance and may be stored in an internal memory of the optical fiber link monitoring apparatus.

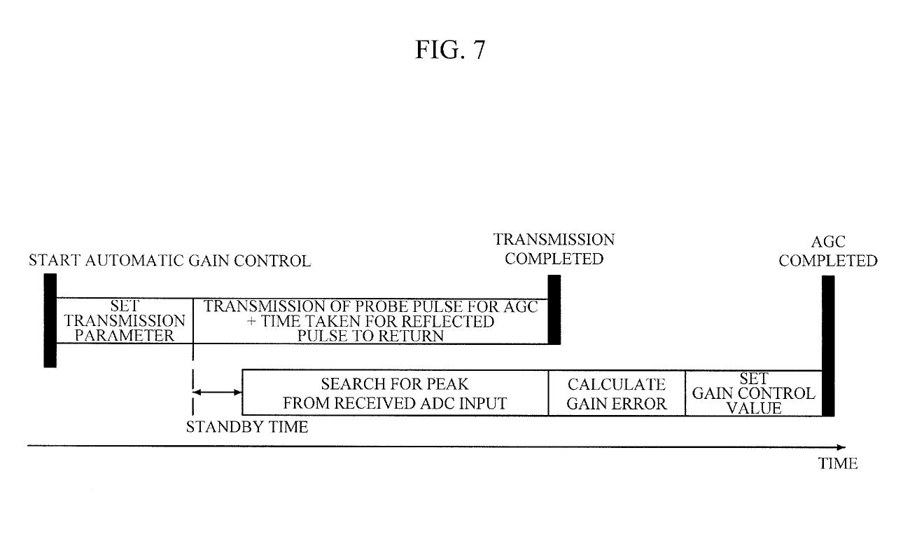

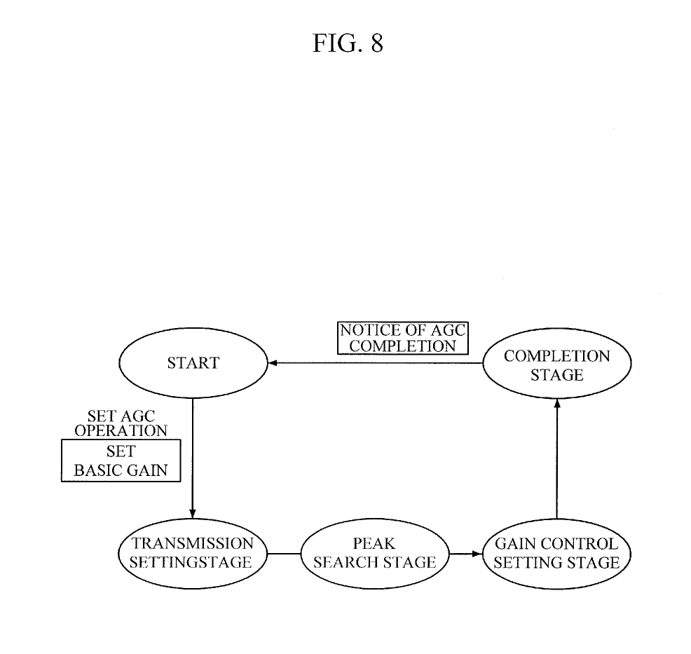

For the purpose of automatic gain control (AGC), an automatic gain controller 950 of the controller 900 controls the peak finder 910, the gain calculator 930 and the probe pulse code creator 100 for AGC. In one exemplary embodiment, the automatic gain controller 950 sets a transmission parameter for AGC, and controls the probe pulse code creator 100 so that it transmits a transmission pulse for AGC, after which the automatic gain controller 950 waits in standby mode until the transmission pulse output to the optical fiber link returns to the probe pulse code creator 100. Next, the automatic gain controller 950 controls the peak finder 910 to find a peak from an input value from the ADC 800 and then controls the gain calculator 930. After the gain calculator 930 has completed its calculation, the automatic gain controller 950 controls the gain adjustment setting part 940 for setting a gain control terminal of the VGA 700. FIGS. 7 and 8 illustrate examples to help the understanding of said control operation.

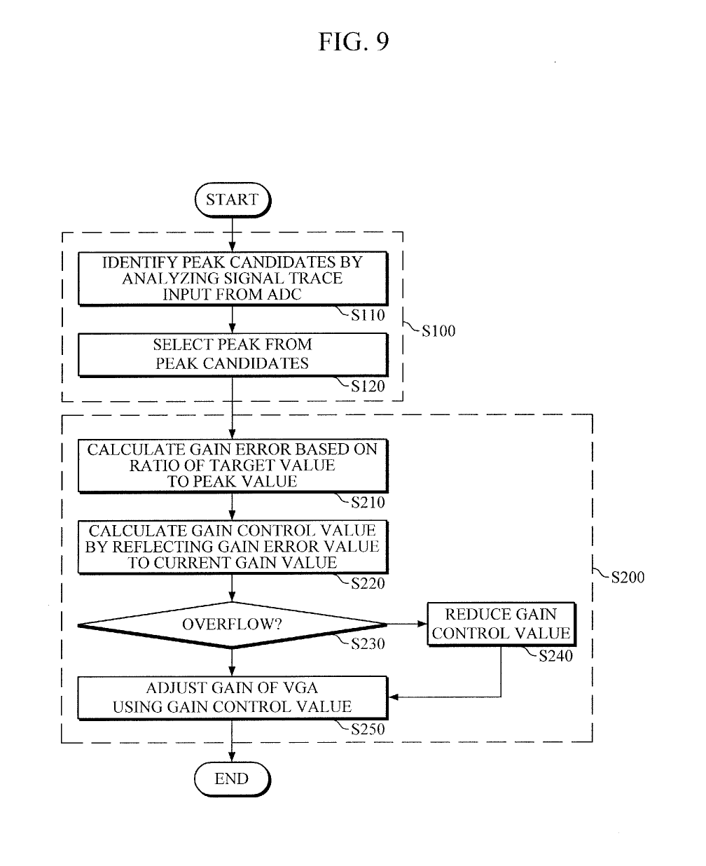

FIG. 9 is a flowchart illustrating a trace-based automatic gain control method according to an exemplary embodiment.

The controller 900 analyzes a signal trace for AGC input from the ADC 800 in order to control a gain of the VGA 700, as depicted in S100. Operation S100 includes operation S110 and S120. In S110, the signal trace input from the ADC 800 is analyzed to identify peak candidates. The peak candidates are determined based on a current input sample value r(n), an input sample value r(n−1) delayed by an increment of one sample and another input sample value r(n−2) delayed by increments of two samples. If the input sample value r(n−1) delayed by an increment of one sample is the greatest, a point corresponding to said input sample value r(n−1) is identified as the peak candidate. In S 120, the highest peak from the peak candidates is determined as the final peak from among the peak candidates.

After the completion of S 100, the controller 900 adjusts a gain of the VGA 700 according to the result of S100. S200 includes operations S210, S220, and S250, and may further include S230 and S240. In S210, a gain error is calculated based on a ratio of a target value to a peak value. The gain error value may be obtained by Equation 3 above. In S220, a gain control value is calculated by adding the gain error to the current gain value. In S250, the gain of the VGA 700 is adjusted using the calculated gain control value. As described above, due to the added gain value, an overflow may occur. The controller 900 determines whether an overflow has occurred, as depicted in S230, and if indeed an overflow has occurred, the controller 900 may reduce the gain control value by a designated value, as depicted in S240.

According to the above exemplary embodiments, a peak in an optical time-domain reflectometer (OTDR) trace is searched in order to provide an automatic gain control with respect to a varying PAR of said trace, and the gain is adjusted according to the found peak, so that a dynamic range of the ADC can be fully utilized, regardless of the PAR, and thereby SNR degradation can be prevented.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An optical fiber link monitoring apparatus for detecting a failure in an optical fiber link by analyzing a trace of a received signal which has been transmitted to and reflected from the optical fiber link, the optical fiber link monitoring apparatus being capable of trace-based automatic gain control and comprising:
a variable gain amplifier (VGA) configured to amplify a gain of the received signal;
an analog/digital converter (ADC) configured to convert a gain-amplified signal into a digital signal; and
a controller configured to analyze a digital signal trace and control a gain of the VGA according to the analysis result.

2. The optical fiber link monitoring apparatus of claim 1, wherein the controller comprises:
a peak finder configured to search for a peak in the digital signal trace and
a gain adjuster configured to adjust the gain of the VGA according to the found peak.

3. The optical fiber link monitoring apparatus of claim 2, wherein the peak finder comprises
a peak candidate identifier configured to determine a peak candidate based on a current input sample value input from the ADC, a previous input sample value delayed by an increment of one sample and another previous input sample value delayed by increments of two samples, wherein when the one-sample-delayed input sample value is the greatest, the peak candidate identifier determines the one-sample-delayed input sample value as a peak candidate, and
a peak selector configured to select a peak from peak candidates.

4. The optical fiber link monitoring apparatus of claim 2, wherein the gain adjuster calculates a gain error based on a ratio of a target value to a peak of the trace, calculates a gain control value by reflecting the gain error to a current gain value, and adjusts the gain of the VGA using the gain control value.

5. The optical fiber link monitoring apparatus of claim 4, wherein in response to occurrence of an overflow in which an amplitude of an input signal exceeds an input range of the ADC, the gain adjuster reduces the gain control value.

6. The optical fiber link monitoring apparatus of claim 2, wherein the gain adjuster searches for a gain control value that corresponds to a target value and the peak of the trace from a lookup table, and adjusts the gain of the VGA using the found gain control value.

7. The optical fiber link monitoring apparatus of claim 6, wherein in response to occurrence of an overflow in which an amplitude of an input signal exceeds an input range of the ADC, the gain adjuster reduces the gain control value.

8. The optical fiber link monitoring apparatus of claim 2, wherein the controller further comprises an automatic gain controller configured to control transmission of a probe pulse for automatic gain control (AGC) and controls operations of the peak finder and the gain adjuster after a designated period of time since the transmission of the probe signal.

9. A trace-based automatic gain control (AGC) method applied to an optical fiber link monitoring apparatus which comprises a variable gain amplifier (VGA) to amplify a gain of a received signal that has transmitted to and reflected from an optical fiber link, and an analog/digital converter to convert the gain-amplified signal into a digital signal, the trace-based AGC method comprising:
analyzing a digital signal trace; and
adjusting a gain of the VGA according to the analysis result.

10. The trace-based AGC method of claim 9, wherein:
the analysis of the digital signal trace comprises searching for a peak in the digital signal trace, and
the adjusting of the gain comprises adjusting the gain of the VGA according to the found peak.

11. The trace-based AGC method of claim 10, wherein the search of the peak comprises
determining a peak candidate based on a current input sample value input from the ADC, a previous input sample value delayed by an increment of one sample and another previous input sample value delayed by increments of two samples, wherein when the one-sample-delayed input sample value is the greatest, the one-sample-delayed input sample value is determined as a peak candidate, and
selecting a peak from peak candidates.

12. The trace-based AGC method of claim 11, wherein the adjusting of the gain comprises
calculating a gain error based on a ratio of a target value to a peak in the trace,
calculating a gain control value by reflecting the gain error to a current gain value, and
adjusting the gain of the VGA using the gain control value.

13. The trace-based AGC method of claim 12, wherein the adjusting of the gain comprises, in response to occurrence of an overflow in which an amplitude of an input signal exceeds an input range of the ADC, reducing the gain control value.
